(19) United States
(12) Patent Application Publication
(10) Pub. No.: US 2021/0233824 A1
(43) Pub. Date: Jul. 29, 2021

(54) CHIP CORNER GUARD FOR CHIP-PACKAGE INTERACTION FAILURE MITIGATION

(71) Applicant: International Business Machines Corporation, Armonk, NY (US)

(72) Inventors: Shidong Li, Hopewell Junction, NY (US); Kamal K. Sikka, Poughkeepsie, NY (US); Charles L. Arvin, Poughkeepsie, NY (US); Steven P. Ostrander, Poughkepsie, NY (US)

(21) Appl. No.: 16/750,270

(22) Filed: Jan. 23, 2020

(51) Int. Cl. H01L 23/24; H01L 25/00; H01L 23/498

(52) U.S. Cl. CPC H01L 23/24; H01L 23/10; H01L 23/498; H01L 25/50

(57) ABSTRACT

An integrated circuit (IC) package, and a method for fabricating an IC package is described. A set of semiconductor chips, a set of corner guard structures and a chip carrier are provided. The set of semiconductor chips and the set of corner guard structure placed and bonded to a first surface of the chip carrier. The set of semiconductor chips are in electrical contact with the chip carrier. Respective corner guard structures are placed proximate to the corners of respective semiconductor chips. The coefficient of thermal expansion (CTE) of the set of corner guard structures is selected to ameliorate chip-package interaction (CPI) related failures due to differences between a CTE of the set of semiconductor chips and a CTE of the chip carrier.

### BACKGROUND OF THE INVENTION

This disclosure relates to integrated circuit devices, and more specifically, to a method and structure to fabricate an advanced packaging structure for connecting integrated circuits, for example, integrated circuits on semiconductor chips.

Chip-package interaction (CPI) related failures are a major challenge for integrated circuit (IC) packaging solutions. These types of failures are caused by a coefficient of thermal expansion (CTE) mismatch, i.e. difference, between the materials that make up the chip carrier and the semiconductor chip. For example, a silicon chip, used to fabricate most integrated circuit devices, has a CTE of approximately 3 ppm/° C., while the typical laminate wiring board used as a chip carrier has a CTE of approximately 16 ppm/° C. The chip and chip carrier are typically joined at an elevated temperature. While cooling down from the chip joining temperature, the wiring board tends to shrink more than silicon chip, thus causing shearing stresses in the chip/laminate interface. These shearing forces, when combined with defects in chip and chip carrier elements, lead to catastrophic CPI failures. Coefficient of thermal expansion mismatch between the chip and the laminate causes the package to deform with temperature fluctuations during the operation of the integrated circuit devices as well.

Chip-package interaction (CPI) related defects particularly occur in the solder joints and in elements in the upper levels of the chip created in the “back-end of the line” (BEOL) processes. For semiconductor chips mounted on conventional chip carriers, maximum stresses are usually located at the corners of the chip.

The prior art has attempted to ameliorate chip-package interaction (CPI) fails in a variety of ways. A laminate chip carrier with a lower CTE mismatch with a semiconductor chip would create lower CTE stresses, and therefore, fewer CPI fails. While in theory a low mismatch CTE laminate chip carrier, that is, a chip carrier with the same or similar CTE as the semiconductor chips, is an “ideal” solution for reducing CPI stresses, a compatible CTE laminate chip carrier is not always an option because of cost, material or electrical performance considerations.

Other prior art has attempted to “toughen” the materials and/or structures used in the BEOL processes and layers. Tougher BEOL layers can be created by using a crack stop structure to mitigate CPI related cracking risks. The BEOL layers themselves can be fabricated using a tougher material. However, a crack stop structure adds complexity to the semiconductor chip and adds expense to the fabrication process. Further, mitigating CPI related stress using tougher materials at the expense of the electrical performance of the chip is not always desirable. That is, the insulator material with a better dielectric constant usually does not also possess better mechanical properties.

The present disclosure presents an advanced packaging approach for mitigating CPI related stresses and faults including cracks in the semiconductor chip.

### BRIEF SUMMARY

According to this disclosure, a device, i.e., an integrated circuit (IC) package, and a method for fabricating an IC package is described. A set of semiconductor chips, a set of corner guard structures and a chip carrier are provided. The set of semiconductor chips and the set of corner guard structure placed and bonded to a first surface of the chip carrier. The set of semiconductor chips are in electrical contact with the chip carrier. Respective corner guard structures are placed proximate to the corners of respective semiconductor chips. The coefficient of thermal expansion (CTE) of the set of corner guard structures is selected to ameliorate chip-package interaction (CPI) related failures due to differences between a CTE of the set of semiconductor chips and a CTE of the chip carrier.

The foregoing has outlined some of the more pertinent features of the disclosed subject matter. These features should be construed to be merely illustrative. Many other beneficial results can be attained by applying the disclosed subject matter in a different manner or by modifying the invention as will be described.

### BRIEF DESCRIPTION OF THE DRAWINGS

For a more complete understanding of the present invention and the advantages thereof, reference is now made to the following descriptions taken in conjunction with the accompanying drawings which are not necessarily drawing to scale, and in which:

FIG. 1 is a quarter symmetrical, top view drawing of a semiconductor chip mounted on a chip carrier showing the chip-package interaction (CPI) stresses;

FIG. 2 is a top view of a set of semiconductor chips and chip guards mounted on a chip carrier according to a first embodiment of the invention;

FIG. 3 is a top view of a set of semiconductor chips and chip guards mounted on a chip carrier according to a second embodiment of the invention;

FIG. 4 is a top view of a set of semiconductor chips and chip guards mounted on a chip carrier according to a third embodiment of the invention;

FIG. 5 is a top view of a set of semiconductor chips and chip guards mounted on a chip carrier according to a fourth embodiment of the invention;

FIG. 6 is a quarter symmetrical, perspective view of a semiconductor chip and chip guard mounted on a chip carrier according to an embodiment of the invention;

FIG. 7 is a quarter symmetrical, top view of a semiconductor chip and chip guard mounted on a chip carrier depicting dimensions of the chip guard and set-off from the chip according to an embodiment of the invention;

FIG. 8 is a diagram showing the modeling results of chip-package interaction (CPI) stress reduction (BEOL corner delamination) using one embodiment of the invention;

FIG. 9 is a diagram showing the modeling results of resin cracking reduction using one embodiment of the invention;

FIG. 10 is a diagram showing the modeling results of Thermal Interface Material (TIM) tearing reduction using one embodiment of the invention; and

FIG. 11 is a flow diagram of an exemplary process to fabricate an assembly according to embodiments of the invention.

### DETAILED DESCRIPTION OF THE DRAWINGS

At a high level, embodiments of the invention use a chip guard placed proximate to a semiconductor chip on a chip carrier. Both the chip guard(s) and the chip(s) are attached to the chip carrier. In preferred embodiments, the same attachment process is used to attach the chip guard(s) and chip(s) to the chip carrier. In embodiments of the invention, because the greatest stresses occur at the chip corners, the chip guards are placed close to corners of the semiconductor chip they are intended to protect from CPI fails. Because the chip guard is placed close to a corner of the semiconductor chip in preferred embodiments, it is also referred to as a “corner guard” in this description. In an exemplary embodiment, four chip guards are each placed tightly adjacent to a respective corner of the semiconductor chip. For example, when a silicon chip is to be protected, the chip guards may be diced or otherwise produced from a dummy silicon wafer in an embodiment of the invention.

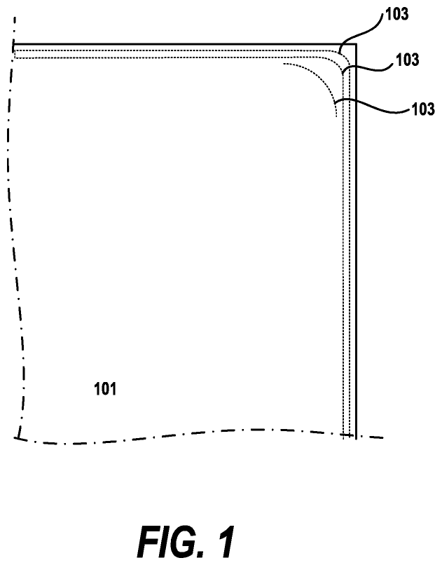

FIG. 1 is a quarter symmetrical, top view drawing of a semiconductor chip mounted on a chip carrier showing the chip-package interaction (CPI) stresses. CPI stresses are highly distance to neutral point (DNP) dependent. The drawing is an exemplary contour map of CPI stress at a corner of a semiconductor chip. The chip 101 is shown with a set of contour lines 103, each contour line representing a specific stress. The chip 101 is mounted on chip carrier (not shown) in a typical manner, e.g., an array of ball limiting metallurgy (BLM) contacts between chip and substrate. As can be seen by the contour lines, the maximum CPI stresses reside at the corners of the chip and the CPI stress decays very quickly with the distance from the chip corner.

The contour map suggests that a method to reduce CPI related defects would be to use a large kerf at the edge of the chip, i.e. locating the active components inward with respect to the corner on the chip. While such a design choice would significantly reduce the CPI stress at the active region containing the circuitry, it does not eliminate the problem. This is because once a crack defect at the semiconductor chip corner occurs, the crack will quickly propagate to the active circuitry zone of the chip. Thus, in the inventors' opinion intentionally increasing the kerf size of the chip will be ineffective in many applications. Another factor is that an increased kerf size means a larger diced chip size (keeping the area of the active area of the chip equal) and so the stress at the chip corner increases which aggravates the risk of CPI induced failures. To protect the solder from fatigue and to insulate the solder balls which attach the chip and chip carrier from bridging due to a mechanism called tin-whiskering, the solder array typically is underfilled with an epoxy-type material. The underfill mechanically couples the entire chip area with the corresponding region in the carrier. As a result, the stress at the chip corner increases rapidly due to high DNP as well as reduced sectional area (radially).

As discussed above, one possible solution to CPI induced defects would be to choose a chip carrier with a similar to that of the chip. With a laminated wiring board, the effective CTE is dominated by copper; 60%-90% of the typical wiring layer is copper. Thus, there are limited material changes that can be made to the chip carrier to bring the chip carrier CTE closer to that of the chip. In preferred embodiments, the invention does not replace the use of crack stops (also known as “seal rings”), but augments the protection offered by crack stops. While crack stops are useful, a crack stop chip does not have infinite resistance to cracking or other CPI induced defects. The invention helps to reduce the crack driving force at the chip corners.

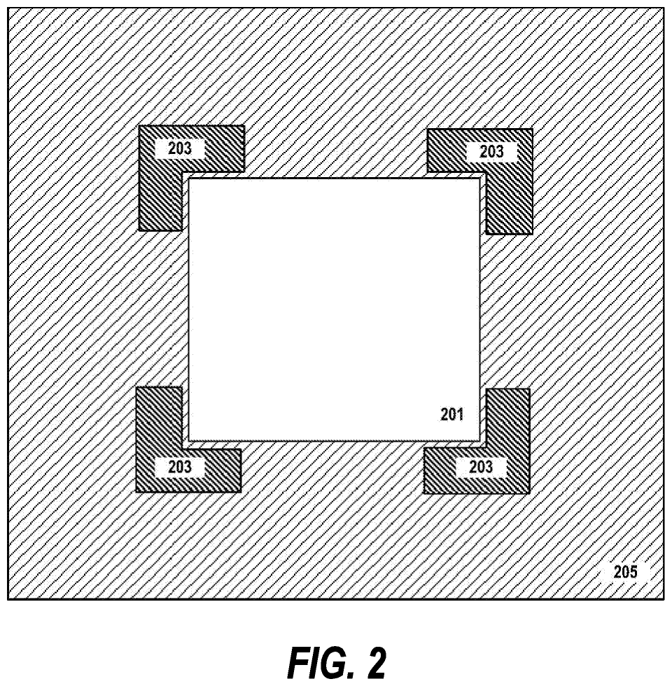

FIG. 2 is a top view of a set of semiconductor chips and chip guards mounted on a chip carrier according to a first embodiment of the invention. In this embodiment, the chip guard(s) 203 are “L-shaped” and mounted to the chip carrier proximate to the corner(s) of the semiconductor chip 201. They are oriented so that each “leg” of a respective “L”-shaped corner guard structure is aligned parallel to an edge of a semiconductor chip. As used in this disclosure, a “leg” is an elongated segment of the chip guard with the elongated dimension parallel to a chip edge. In the drawing, only a single semiconductor chip is illustrated, however, those skilled in the art will appreciate that in embodiments of the invention in which a plurality of chips are in the set of chips. In such embodiments, each of the semiconductor chips mounted on the chip carrier can be accompanied by a set (which may be a plurality) of corner guards.

In a preferred embodiment, the semiconductor chip 201 is silicon, however, in alternative embodiments, other semiconductors can be used. In a preferred embodiment, where the semiconductor chip is silicon based, the chip guard 203 can be bare silicon. In other embodiments, the chip guard 203 is selected to have a CTE similar to that of the semiconductor comprising the chip 201, or another material that has a similar CTE and does not jeopardize electrical functionalities, e.g., cause short defects. For example, the CTE of silicon is 3.2 ppm/° C., so a “similar CTE” for the chip guard would have a CTE between 0 and 7 ppm/° C., preferably between 3-3.5 ppm/° C. In other embodiments, the chip guard is comprised of material having a CTE intermediate between the CTE of the chip carrier 205 and the CTE of the chip 201. Thus, embodiments have chip guards comprised of the same or similar semiconductor as that which comprises the chip. In other embodiments, a glass or a ceramic material would have the good CTE properties and the desired mechanical strength and can be used as a chip guard.

By mounting structural components to the chip carrier adjacent to the high DNP regions of semiconductor chips, i.e. the corners, the structural components serve as “corner guards”. Each corner guard reduces the CPI defect risks for the respective semiconductor corner. For a particular semiconductor chip, corner guards made of the same semiconductor, e.g., dummy silicon for a silicon chip, is a cost effective solution. Further, the corner guards can be accurately and concurrently placed with the associated chips using the same bond and assembly techniques used for placing the chips on the carrier. As shown, in embodiments, each of the chip corners (i.e. high DNP regions of the chip) are protected by the corner guards.

In respective embodiments, corner guards can be mounted to the chip carrier in different ways. One preferred solution is to solder join the corner guards to prefabricated dummy pads on the chip carrier followed by a underfill process. This method allows the corner guard to be self-aligned through surface tension effect of molten solder. Other methods used in other embodiments include a direct attachment with a fast curing adhesive (e.g., epoxy) between chip carrier and chip guard.

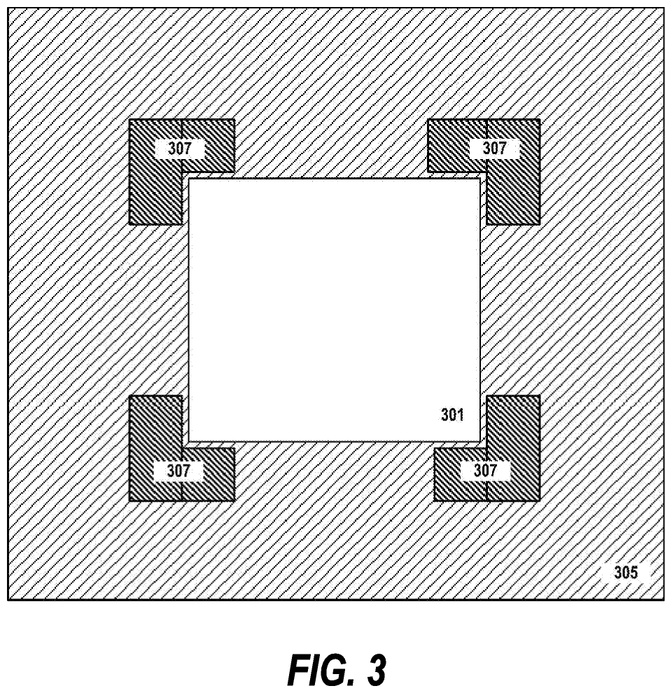

FIG. 3 is a top view of a set of semiconductor chips and chip guards mounted on a chip carrier according to a second embodiment of the invention. As shown in the embodiment, a chip 301 is mounted on the laminate chip carrier 305. The L-shaped corner guard 307 can be formed by two or more rectangular pieces of the corner guard material. Although shown as two pieces in the drawing, corner guard 307 could be formed by two rectangles and a square in other embodiments. By assembling the corner guard 307 from two or more pieces, a material savings is achieved, i.e. more of the corner guards can be made from the same wafer as compared to cutting “cut-outs” from a square piece of wafer for the embodiment of FIG. 2. The cutting process is also easier. However, the assembly process of placing a greater number of pieces for each corner guard is more difficult, so there is a trade-off between the material costs and process complexity of the individual steps. Because the joint is not in the same line with the diagonal of the chip, the weakening between a single piece corner guard and a multiple piece is marginal. The fact that the joint gap will be filled with adhesive further decreases the weakening effect.

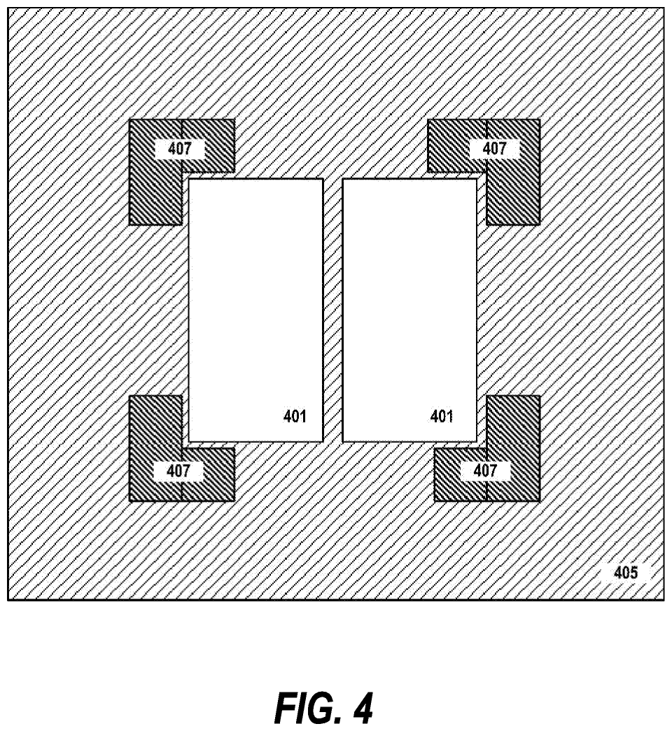

FIG. 4 is a top view of a set of semiconductor chips and chip guards mounted on a chip carrier according to a third embodiment of the invention. In the drawing, multiple chips 401 are mounted to a multiple chip module (MCM) chip carrier 405 using standard techniques. An MCM is an electronic package that has more than one semiconductor chip integrated onto a unifying substrate. When chips are packaged more compactly in an MCM, there is a performance advantage over an equivalent number of single chip modules (SCM). In one preferred embodiment, corner guards can be made of the same material as discussed above for an SCM. In the illustrated embodiment, the L-shaped corner guards 407 are two piece corner guards like the second embodiment, however, one piece L-shaped corner guards or other shaped corner guards can used in alternative embodiments at the available corners of multiple chips 401 for stress protection. This embodiment shows that the corner guards can be placed at some of the chip corners, but not all of the chip corners.

Due to the proximity of the adjacent chips 401 on an MCM 405, the chips themselves provide some ameliorative effect for relieving strain for another proximate chip. In an embodiment of the invention, depending on the proximity of respective chips to each other, a decision is made during the design phase as to whether a corner guard is required or not. In alternative embodiments, where the space between chips is relatively small, but still larger than optimal, a different dimensioned corner guard can be inserted. A “skinny” corner guard would be useful where the chips are close, but not so close that they would prevent the skinny corner guard from being slipped between adjacent chips. Placement and joining will be challenging for a skinny corner guard, but it will help with the CPI stresses. In one preferred embodiment, a “skinny corner guard” is ½ to ⅓ the width dimension of a normal corner guard.

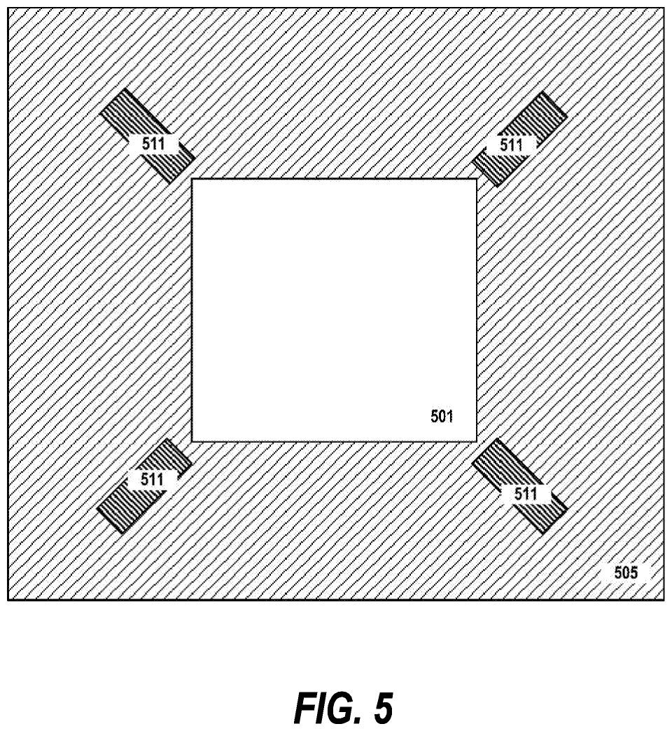

FIG. 5 is a top view of a set of semiconductor chips and chip guards mounted on a chip carrier according to a fourth embodiment of the invention. As in in other embodiments, the chip guards 511 are comprised of silicon or another material that does not deleteriously affect the electrical functionalities of the chip 501 or chip carrier 505. The drawing is intended to illustrate that other shaped corner guards are used in other embodiments of the invention. In the drawing, a plurality of rectangular corner guards 511 are mounted to the chip carrier 505 at the chip corners in a diagonal direction with respect to the chip 501. It is easiest, and therefore, least expensive to use rectangular or square corner guards. As is discussed herein, the chip corner is the chip location most susceptible to CPI induced defects. Therefore, preferred embodiments locate a chip guard at the chip corner. In a variant of this embodiment, a rectangular or square corner guard is mounted to the chip carrier at the corner and parallel to one of the chip edges (rather than oriented diagonally with respect to the corner).

Some coverage by the corner guard adjacent to the corner along both edges of the chip is also desirable. In another variant of this embodiment, a 90 degree notch in one end of each of the corner guards can provide greater protection at the expense of greater complexity in fabrication and placement of the corner guards. In this variant, the notch in the corner guard is mounted proximate to the corner of the semiconductor chip.

Although not illustrated, embodiments of the invention can use a mixture of different shaped corner guards on the same chip carrier; depending on the geometry of the chip placement on the chip carrier different corner guards are selected for particular chip corners. For example, where chips are closely spaced, thinner corner guards are used. In embodiments of the invention, a single corner guard may provide protection to more than one chip, e.g., placed between two chip corners. In such situations, a T-shaped corner guard can be used. Where chips are spaced with greater distances, thicker, individual corner guards can be accommodated (e.g., L-shaped corner guards).

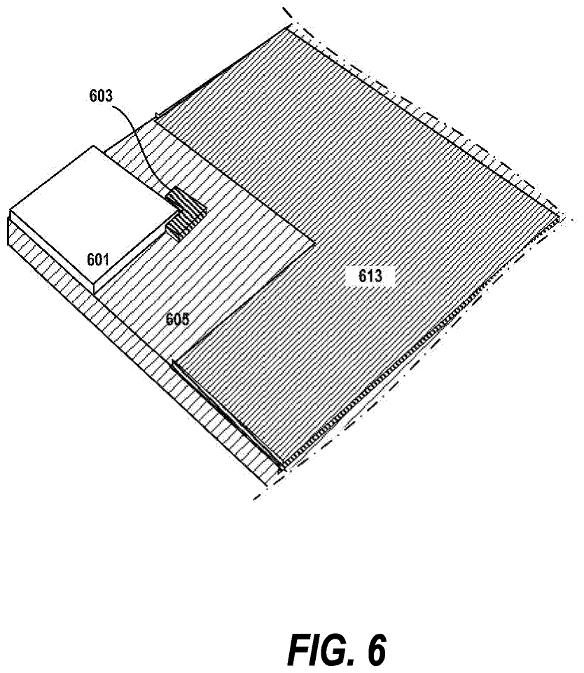

FIG. 6 is a perspective view of a semiconductor chip and chip guard mounted on a chip carrier according to an embodiment of the invention showing a corner guard on one corner of the semiconductor chip. The view is a quarter symmetric model as only a quarter of the assembly is shown in the drawing of a single chip module (SCM) package. That is, in preferred embodiments, a corner guard is placed on each corner of the chip. Semiconductor chip 601 and corner chip guard 603 are bonded to chip carrier layer 605. Sealband 613 is also shown. In the drawing, the lid is hidden to show the internal layout. As is known, the lid would be bonded to the chip carrier substrate 605 by means of the sealband 613. As shown, the L-shaped embodiment of the corner guard is used. The L-shaped embodiment has a geometric advantage where a chip is proximate to the sealband which attaches the lid because of the proximity to the sealband.

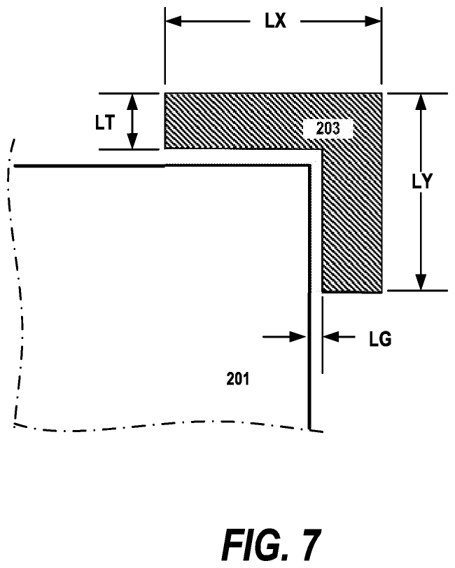

FIG. 7 is a top view of a semiconductor chip and chip guard mounted on a chip carrier depicting dimensions of the chip guard and the chip guard set-off from the chip according to an embodiment of the invention. The corner of the chip 201 is protected by corner guard 203. For ease in illustration, only the chip guard at one corner is illustrated. The LX parameter is the length of the corner guard in the X direction; the LY parameter is the length in the Y-direction. The LT parameter represents the thickness of the corner guard 203 and the LG parameter represents the gap between the corner guard 203 and the edge of the chip 201. This model presumes that the LT dimension is the same for both the X and Y dimensions. These dimensions were varied in a set of models to see which dimensions of an L-shaped corner guard were most important.

The modeling parameters included a chip carrier body size of 68.5 mm×68.5 mm and a chip size of 23 mm×28 mm. One skilled in the art will recognize that many different assumptions for chip and chip carrier size will result in different optimizations. A laminate substrate was used as the chip carrier, e.g., a 7-2-7 GZ41/E705G laminate. A silicon chip and a silicon corner guard were used in the modelling. The Thermal Interface Material (TIM) was TC3040, a Dow Corning product; the seal band material was EA6700 also a Dow Corning product. The modeling results showed that an installed corner guard provided up to 85% reduction in CPI stresses at the chip corner with a marginal cost of slightly increased seal band stress and

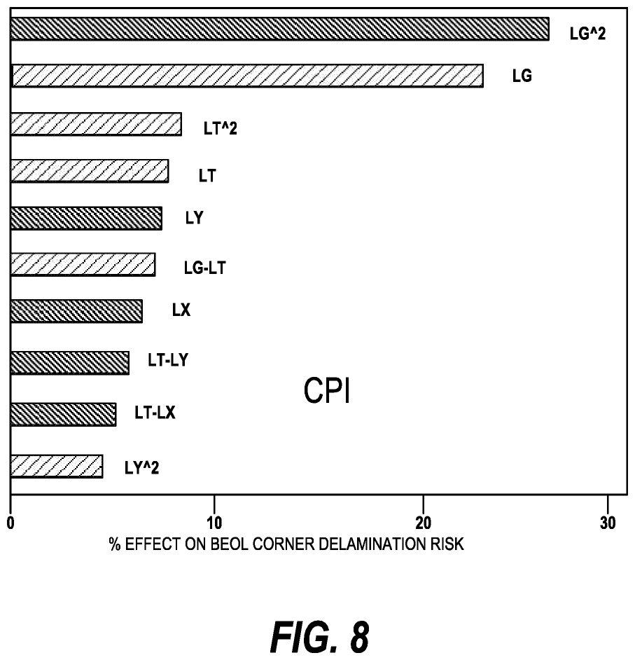

FIGS. 8-10 are diagrams showing the modeling results of chip-package interaction (CPI) stress reduction using the L-shaped corner guard embodiment of the invention. The modeling shows that a corner guard can drastically reduce CPI stresses (up to 85%). The corner chip guard mitigates CPI stresses causing chip failure or dielectric resin cracking in the laminate chip carrier (e.g., bottom-side metallization (BSM) side. Further, a corner guard also improves TIM integrity. The modeling shows that the corner chip guard does not lead to any significant stress increases which might cause other reliability issues to the chip/chip carrier assembly.

In FIG. 8, the top dimension contributors of the corner guard for reducing BEOL corner delamination risks, one of the CPI induced defects are shown. The LG parameter represents the gap between the corner guard and the edge of the chip. Modelling results indicate that a small LG is most effective. That is, the closer the corner guard is placed to the corner of the chip the more successful it will be. When modelling LT, the thickness of the corner guard laterally, it was found that a wider LT was better for reducing CPI stress. It was found that only a relatively short LX, LY was needed to be effective in reducing CPI failures. These results suggest that for CPI failures on the chip side, having an L-shaped corner guard with relatively short, but wide legs are the most effective use of corner guard material.

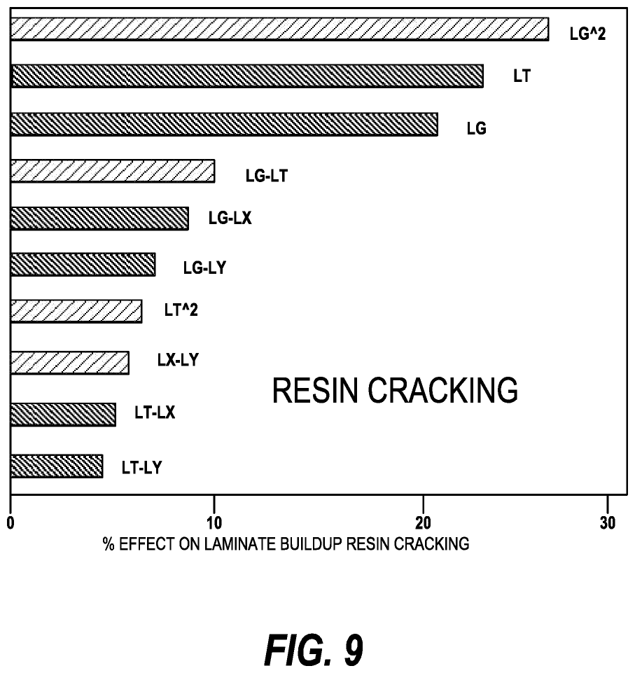

FIG. 9 is a diagram showing the modeling results of resin cracking reduction using the L-shape embodiment of the invention. In modelling, it was found that a wider LT was better but that a larger LG was more effective which is different than the CPI stress result. Also, it was found that resin cracking was not sensitive to variations in the LX, LY lengths.

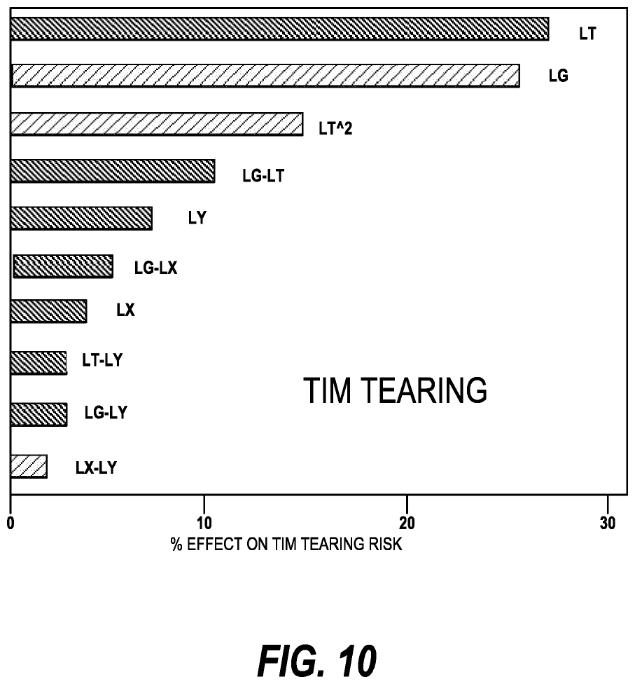

FIG. 10 is a diagram showing the modeling results of TIM tearing reduction using one embodiment of the invention. In modelling, for TIM tearing, it was found that a wider LT was better and that a smaller LG was more effective which is like the CPI stress result, but different from the resin cracking result. Also, it was found that TIM tearing reduction was not sensitive to variations in the LX, LY lengths.

In embodiments where “L-shaped” chip guards are used, a thickness ranging 0.5t to 1.0t is preferable, where t is the thickness of the chip. Other thicknesses as measured in comparison to the chip are within the contemplated scope of the invention. A thicker chip guard as compared to the chip may be preferred in certain embodiments but will require changes in the case lid or case lid set-off. As mentioned above, according to modelling, the gap distance between the chip and chip guards should be minimized. A 150 um spacing between the chip and chip guards can be achieved with current chip placement techniques, but chip placement techniques may be improved in the future leading to smaller gaps. As the width (the LT dimension) of the corner guard should be wide, in comparison to the overall dimensions of the chip guard, in preferred embodiments, the width of an L-shaped corner guard should be to be 0.5 mm or larger. For chip sizes from 400 mm² to 700 mm², LX/LY dimensions of 3-4 mm alleviate the majority of the CPI stress. Performance gains from a larger corner guard is marginal compared to material costs and the needed changes in the chip placement.

CPI risk is highly dependent on the stresses at DNP areas of the chip which increase with the size of the chip. The need for chip guards increases with the increasing chip size. CPI delamination becomes a problem for chip sizes greater than 225 mm². Modeling shows that value of chip guards becomes even greater for chip sizes greater than 400 mm². At these chip dimensions, dramatic curvature changes cause the CPI stress to rise sharply at the chip corners. The CPI stresses are mainly caused by the CTE mismatch between the chip carrier and chip. That is, chips and chip carriers with highest CTE mismatch would benefit from the current invention most. While the lid also influences the CPI stress by forcing chip to flatten, it is not the primary factor.

Other shapes of corner guards are contemplated in embodiments of the invention; they may work less effectively. In modelling, an L-shaped edge/corner guard covering the corner of the chip, but not the entire chip length, is optimal in terms of reducing stress and material expenditures for the chip guard. As the material for the chip guard relative to the chip itself, which contains multiple device layers, is inexpensive, longer legs on the corner guard will work in embodiments of the invention. There is a tradeoff between cost in materials, difficulty of placing the corner guard in a fabrication process and amelioration of the CPI stresses which will vary according to the chip and chip carrier design. Among the corner guard shapes contemplated by the inventors include L-shaped bumpers, rectangular bumpers, ¾ of a circular pie shaped bumpers. One parameter is to keep the chip guard close to the chip corner or other locations susceptible to cracking.

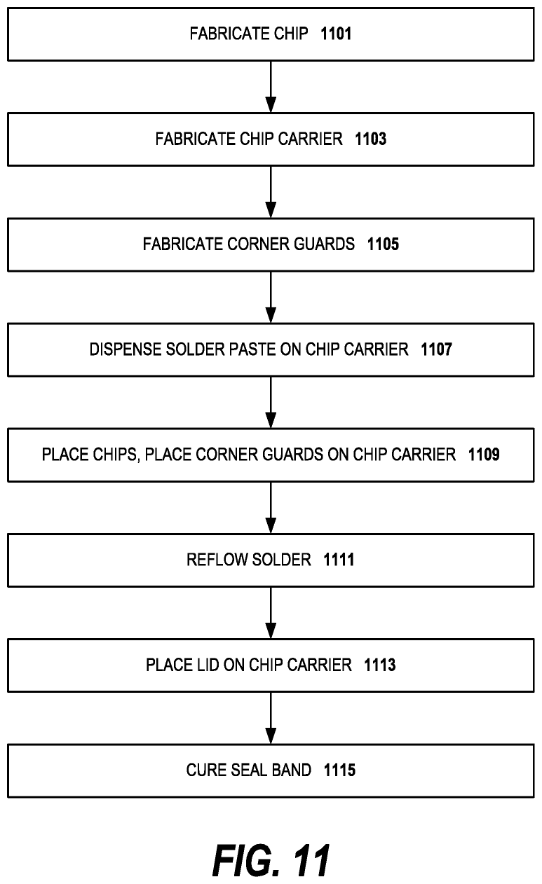

A flow diagram of an exemplary process to fabricate an assembly according to embodiments of the invention is shown in FIG. 11. In step 1101, the semiconductor chip, e.g., a silicon chip, is fabricated according to known processes. Of pertinence to the present invention, a set of metallic pads are formed in an upper level of the chip to provide an electrical and physical connection to the chip carrier. In step 1103, the chip carrier, e.g., a PCB board, is fabricated according to known processes. Like the chip, a set of contact pads is formed on an upper surface of the chip carrier to provide electrical and physical connections to the chips which will be mounted onto the chip carrier.

“Dummy” pads are created for the corner guards in the chip carrier. The pad dimensions and types are the same as used for the chip in some embodiments. However, in preferred embodiments, to ease the bond and assembly, the feature size of these pads is preferred to be larger than those of the chips

In step 1105, the corner chip guards are fabricated. As discussed above, in preferred embodiments, the corner guards are fabricated from the same material as the semiconductor chip. For example, corner guards for a silicon chip can be fabricated by dicing a raw silicon wafer. As the corner guards are not intended to be electrically functional, the fabrication process is simple as compared to that of the chip or chip carrier, comprising largely of forming the pads and cutting the guards to size.

Anchoring pads on glass substrate or ceramic substrate can be fabricated through plating, the technique of which is well established.

In step 1107, solder paste or an alternative bonding agent is applied to the pads of the chip carrier.

In step 1109, the chips and corner guards are placed on the appropriate pads of the chip carrier using known chip placement processes. In different embodiments, the chips or the corner guards can be placed first or the chip and corner guard placement can be comingled. For example, in one preferred embodiment, the chips are placed and inspected before the corner guards are placed.

After placement, the chips and chip guards can be solder reflowed at the same time, in step 1111. In this step, the solder is reflowed, bonding the chips and corner guards to the chip carrier. As is mentioned above, the solder reflow is performed at an elevated temperature. As the assembly cools, CPI stresses occur on the chips but are greatly ameliorated by the presence of the corner guards. In preferred embodiments, there is an underfill step applying a material which underfills both chip and corner guards. Underfills such as epoxy underfill materials are known to those skilled in the art.

In step 1113, the lid is placed on the chip carrier using conventional lid alignment and placement techniques.

In step 1115, the seal band is cured to bond the lid onto the chip carrier. While the curing process occurs at an elevated temperature, in preferred embodiments, the bonding process occurs at a lower temperature than that in step 1111 to avoid reflowing the solder joints of the already bonded chips, corner guards and chip carrier.

As is known, additional steps such as adding contact pads and solder balls to the opposite side of the chip carrier from the chip-chip carrier interface can be used to bond the chip carrier to other components in some embodiments.

The inventors present an inexpensive solution relative to the overall expense of semiconductor processing. The chip corner guard can be cut from dummy silicon wafer. As one example, more than 6000 pieces of 4 mm×4 mm×1 mm “L”-shaped corner guard can be cut out of a 300 mm wafer. At current prices, the material costs of each corner guard would be less than 10 cents each.

In embodiments of the invention, the integrated circuit (IC) package assembly includes one or more semiconductor chip electrically joined to the laminate chip carrier, e.g., with flip chip technology. In flip chip technology, the flip chip solder joints may or may not be encapsulated with underfill. Corner guards are closely placed adjacent to the corners of the chip, say 0.1 mm to 0.5 mm and joined to the laminate chip carrier. In some embodiments, the corner guards are joined to the laminate chip carrier using the same soldering step and technology used for joining the chips to the laminate. In other embodiments, an adhesive such as a high temperature epoxy can be used to join the corner guards.

Silicon is a good material to use for the corner guards when the chip is also silicon. In other embodiments, where the chip is comprised of a different semiconductor, the corner guard material can be selected to match that of the chip. Other materials such as glass or ceramic would have good CTE and desired mechanical robustness and are used in alternative embodiments of the invention. Ceramic and glass can be used as a corner guard material because it has a CTE similar to that of the silicon chip. Ceramic and glass can be fabricated to match a desired CTE by using different formulas and processes.

In a preferred embodiment, the chip carrier is a laminate comprised of a central “core” layer which provides a structurally strong layer for chip placement. The core layer is composed of standard printed circuit board (PCB) material. In this embodiment, the semiconductor chip is comprised of a semiconductor, e.g. a silicon chip. In other embodiments of the invention, other substrates can be used to support the chips such as a ceramic substrate or another substrate amenable to the particular application.

In the structures as described above, and other structures where different components have different coefficients of thermal expansion, the invention has particular applicability.

While only one or a limited number of features are illustrated in the drawings, those ordinarily skilled in the art would understand that many different types of features could be simultaneously formed with the embodiment herein and the drawings are intended to show simultaneous formation of multiple different types of features. However, the drawings have been simplified to only show a limited number of features for clarity and to allow the reader to more easily recognize the different features illustrated. This is not intended to limit the invention because, as would be understood by those ordinarily skilled in the art, the invention is applicable to structures that include many of each type of feature shown in the drawings.

While the above describes a particular order of operations performed by certain embodiments of the invention, it should be understood that such order is exemplary, as alternative embodiments may perform the operations in a different order, combine certain operations, overlap certain operations, or the like. References in the specification to a given embodiment indicate that the embodiment described may include a particular feature, structure, or characteristic, but every embodiment may not necessarily include the particular feature, structure, or characteristic.

In addition, terms such as “right”, “left”, “vertical”, “horizontal”, “top”, “bottom”, “upper”, “lower”, “under”, “below”, “underlying”, “over”, “overlying”, “parallel”, “perpendicular”, etc., used herein are understood to be relative locations as they are oriented and illustrated in the drawings (unless otherwise indicated). Terms such as “touching”, “on”, “in direct contact”, “abutting”, “directly adjacent to”, etc., mean that at least one element physically contacts another element (without other elements separating the described elements).

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

Having described our invention, what we now claim is as follows:

1. A method for fabricating an integrated circuit (IC) package comprising:
providing a set of semiconductor chips, a set of corner guard structures and a chip carrier;
placing and bonding the set of semiconductor chips and the set of corner guard structure to a first surface of the chip carrier, wherein the set of semiconductor chips are in electrical contact with the chip carrier and ones of the set of corner guard structures are placed proximate to corners of ones of the set of semiconductor chips;
wherein a coefficient of thermal expansion (CTE) of the set of corner guard structures is selected to ameliorate chip-package interaction (CPI) related failures due to differences between a CTE of the set of semiconductor chips and a CTE of the chip carrier.

2. The method as recited in claim 1, wherein a corner guard structure is placed proximate to each corner of a semiconductor chip.

3. The method as recited in claim 1, wherein the set of semiconductor chips and the set of corner guard structures are comprised of a same material.

4. The method as recited in claim 1, wherein the set of semiconductor chips and the set of corner guard structures are comprised of silicon.

5. The method as recited in claim 1, wherein a material for the set of corner guard structures is selected to have a similar CTE of the CTE of the set of semiconductor chips.

6. The method as recited in claim 1, wherein the set of corner guard structures are “L”-shaped and are oriented so that each leg of a corner guard structure is aligned parallel to an edge of a semiconductor chip.

7. The method as recited in claim 6, wherein ones of the corner guard structures are formed by two or more rectangular pieces of corner guard material.

8. The method as recited in claim 1, wherein ones of the set of corner guard structures are placed selectively at some of the corners of the set of semiconductor chips, but not all of the corners.

9. The method as recited in claim 1, wherein the set of semiconductor chips and the set of corner guard structures are bonded to the first surface of the chip carrier using a same bonding step.

10. The method as recited in claim 1, wherein the set of semiconductor chips and the set of corner guard structures have an underfill disposed between respective ones of the semiconductor chips and the first surface of the chip carrier.

11. An integrated circuit (IC) package device comprising:
a set of semiconductor chips;
a set of corner guard structures;
a chip carrier;
wherein the set of semiconductor chips and the set of corner guard structure are bonded to a first surface of the chip carrier, wherein the set of semiconductor chips are in electrical contact with the chip carrier and ones of the set of corner guard structures are placed proximate to corners of ones of the set of semiconductor chips;
wherein a coefficient of thermal expansion (CTE) of the set of corner guard structures is selected to ameliorate chip-package interaction (CPI) related failures due to differences between a CTE of the set of semiconductor chips and a CTE of the chip carrier.

12. The device as recited in claim 11, wherein a corner guard structure is placed proximate to each corner of a semiconductor chip.

13. The device as recited in claim 11, wherein the set of semiconductor chips and the set of corner guard structures are comprised of a same material.

14. The device as recited in claim 1, wherein the set of semiconductor chips and the set of corner guard structures are comprised of silicon.

15. The device as recited in claim 11, wherein a material for the set of corner guard structures is selected to have a similar CTE of the CTE of the set of semiconductor chips.

16. The device as recited in claim 11, wherein the set of corner guard structures are “L”-shaped and are oriented so that each leg of a corner guard structure is aligned parallel to an edge of a semiconductor chip.

17. The device as recited in claim 14, wherein ones of the corner guard structures are formed by two or more rectangular pieces of corner guard material.

18. The device as recited in claim 11, wherein ones of the set of corner guard structures are placed selectively at some of the corners of the set of semiconductor chips, but not all of the corners.

19. The device as recited in claim 11, wherein the set of semiconductor chips and the set of corner guard structures are bonded to the first surface of the chip carrier using a same bonding step.

20. The device as recited in claim 11, wherein the set of semiconductor chips and the set of corner guard structures have an underfill disposed between respective ones of the semiconductor chips and the first surface of the chip carrier.
